(19) United States
(12) Patent Application Publication
(10) Pub. No.: US 2025/0106992 A1
(43) Pub. Date: Mar. 27, 2025

(54) ELECTRONIC DEVICE AND METHOD OF MANUFACTURING THE SAME

(71) Applicant: InnoLux Corporation, Miao-Li County (TW)

(72) Inventors: Chen-Kuan KAO, Miao-Li County (TW); Chih-Chang HOU, Miao-Li County (TW)

(21) Appl. No.: 18/810,911

(22) Filed: Aug. 21, 2024

(30) Foreign Application Priority Data
Sep. 26, 2023 (CN) 202311249136.1

(51) Int. Cl. H05K 1/02; H01L 27/12; H05K 3/06; H05K 3/46

(52) U.S. Cl. CPC H05K 1/0298; H05K 3/06; H05K 3/4644; H10D 86/441; H10D 86/60

(57) ABSTRACT

An electronic device is provided. The electronic device includes a substrate, a first metal layer, and a second metal layer. The first metal layer is disposed on the substrate. The first metal layer includes a first edge and a second edge. The second metal layer is disposed on the first metal layer. The first metal layer is located between the substrate and the second metal layer. The first edge does not overlap the second metal layer. The second edge overlaps the second metal layer. A side angle of the first edge is different from a side angle of the second edge. The side angle of the second edge is greater than or equal to 30 degrees and less than or equal to 45 degrees. A method of manufacturing an electronic device is also provided.

This application claims the benefit of China Application No. 202311249136.1, filed Sep. 26, 2023, the entirety of which is incorporated by reference herein.

### BACKGROUND

### Technical Field

The present disclosure is related to an electronic device and a method of manufacturing the same, and in particular it is related to a display device and a method of manufacturing the same.

### Description of the Related Art

Electronic devices equipped with display panels, such as tablet computers, notebook computers, smartphones, monitors and televisions, have become indispensable necessities in modern society. With the ongoing development of these portable electronic devices, consumers have high expectations regarding the quality, functionality or price of these products.

However, these electronic devices have not yet met expectations in all respects. For example, as the resolution increases and the pixel area decreases, how to improve the display quality and process yield is still one of the current research topics in the industry.

### SUMMARY

In accordance with some embodiments of the present disclosure, an electronic device is provided. The electronic device includes a substrate, a first metal layer, and a second metal layer. The first metal layer is disposed on the substrate. The first metal layer includes a first edge and a second edge. The second metal layer is disposed on the first metal layer. The first metal layer is located between the substrate and the second metal layer. The first edge does not overlap the second metal layer. The second edge overlaps the second metal layer. A side angle of the first edge is different from a side angle of the second edge. The side angle of the second edge is greater than or equal to 30 degrees and less than or equal to 45 degrees.

In accordance with some embodiments of the present disclosure, a method of manufacturing an electronic device is provided. The method includes the following steps: providing a substrate; forming a first metal layer on the substrate; performing a patterning process on the first metal layer; and forming a second metal layer on the first metal layer.

The first metal layer includes a first edge and a second edge. In the patterning process, the exposure dose in an area corresponding to the first edge is different from the exposure dose in an area corresponding to the second edge, so that the first metal layer has a different profile at the first edge and the second edge. The first edge does not overlap the second metal layer. The second edge overlaps the second metal layer. A side angle of the first edge is different from a side angle of the second edge. The side angle of the second edge is greater than or equal to 30 degrees and less than or equal to 45 degrees.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1 is a top-view diagram of an electronic device in accordance with some embodiments of the present disclosure;

FIG. 2A is a partial top-view diagram of an electronic device in accordance with some embodiments of the present disclosure;

FIG. 2B is a partial top-view diagram of an electronic device in accordance with some embodiments of the present disclosure;

FIG. 3A is a cross-sectional diagram of the electronic device taken along the section line A-A′ in FIG. 2 in accordance with some embodiments of the present disclosure;

FIG. 3B is a cross-sectional diagram of the electronic device taken along the section line B-B′ in FIG. 2 in accordance with some embodiments of the present disclosure;

FIGS. 4A to 4G are cross-sectional diagrams of an electronic device during the intermediate stages of the manufacturing process in accordance with some embodiments of the present disclosure;

FIGS. 5A to 5C are cross-sectional diagrams of an electronic device during the intermediate stages of the manufacturing process in accordance with some embodiments of the present disclosure;

FIGS. 6A to 6C are cross-sectional diagrams of an electronic device during the intermediate stages of the manufacturing process in accordance with some embodiments of the present disclosure.

### DETAILED DESCRIPTION

The electronic device and the method of manufacturing the same according to the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. For example, the first element in the specification may refer to the second element in the claims.

In accordance with the embodiments of the present disclosure, regarding the terms such as “connected to”, “interconnected with”, etc. referring to bonding and connection, unless specifically defined, these terms mean that two structures are in direct contact or two structures are not in direct contact, and other structures are provided to be disposed between the two structures. The terms for bonding and connecting may also include the case where both structures are movable or both structures are fixed. In addition, the term “electrically connected to” or “coupled to” may include any direct or indirect electrical connection means.

In the following descriptions, terms “about”, “substantially” and “approximately” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between.

It should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with the embodiments of the present disclosure, an electronic device is provided, which includes metal layers with different profiles in particular regions. Specifically, the same metal layer, for example, can have different side angles in different regions. For example, the metal layer has a smaller side angle where it overlaps another metal layer, thereby reducing the problem of electrostatic discharge (ESD) occurring between metal layers and damaging the circuit structure, or further improving the quality of the displayed image. Furthermore, in accordance with the embodiments of the present disclosure, a method of manufacturing the aforementioned electronic device is also provided. The method allows the same metal layer to have different profiles in different regions without increasing the number of masks or the number of deposition and etching steps.

In accordance with the embodiments of the present disclosure, the electronic device may include a display device, an antenna device, a light emitting device, a sensing device, a tiled device, a touch electronic device, a curved electronic device or a non-rectangular electronic device, but it is not limited thereto. The electronic device may include, for example, liquid crystal, light-emitting diode, quantum dot (QD), fluorescence, phosphor, other suitable display media, or a combination thereof, but it is not limited thereto. The electronic device may be a non-self-luminous display device or a self-luminous display device. The electronic device may include passive components and active components, such as capacitors, resistors, inductors, diodes, transistors, etc. The diode may include a light-emitting diode (LED) or a photodiode. The light-emitting diode may include, for example, an organic light-emitting diode (OLED), a mini light-emitting diode (mini LED), a micro light-emitting diode (micro LED) or a quantum dot light-emitting diode (quantum dot LED), but it is not limited thereto. The antenna device may be a liquid-crystal type antenna device or a non-liquid crystal-type antenna device. The sensing device may be a sensing device that senses capacitance, light, heat energy or ultrasonic waves, but it is not limited thereto. The tiled device may be, for example, a tiled display device or a tiled antenna device, but it is not limited thereto. It should be noted that the electronic device can be any combination of the above, but it is not limited thereto. In addition, the electronic device may be a bendable or flexible electronic device. In addition, the shape of the electronic device may be a rectangular shape, a circular shape, a polygonal shape, a shape with curved edges, or other suitable shapes. The electronic device may have peripheral systems such as driving systems, control systems, light source systems, etc. to support display devices, antenna devices, wearable devices (for example, including augmented reality (AR) or virtual reality (VR) devices), vehicle-mounted devices (for example, including car windshield) or tiled devices. For the convenience of description, the electronic device will be described below as a display device, but the present disclosure is not limited thereto.

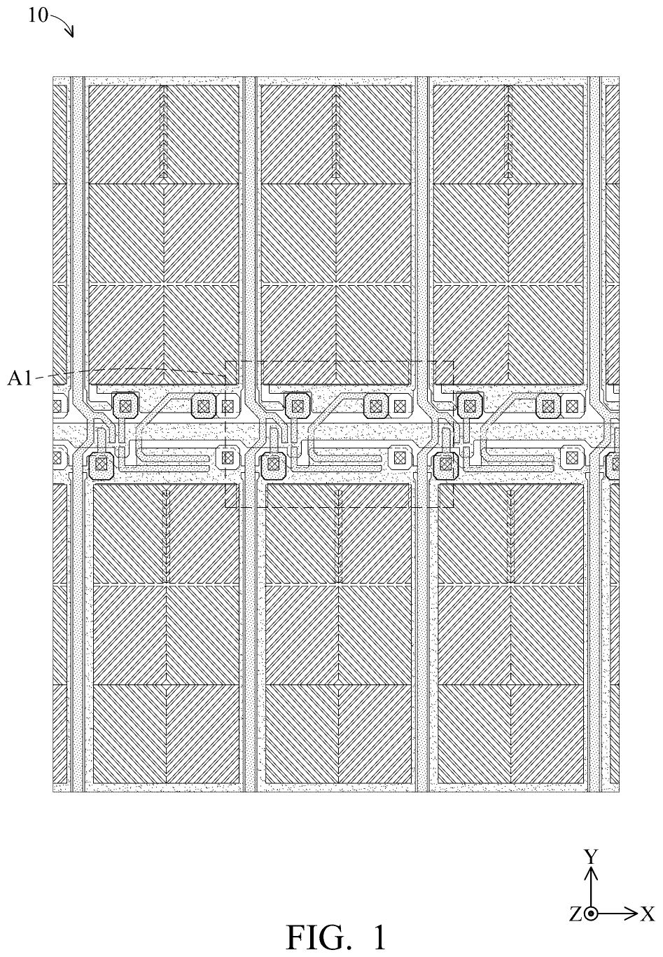

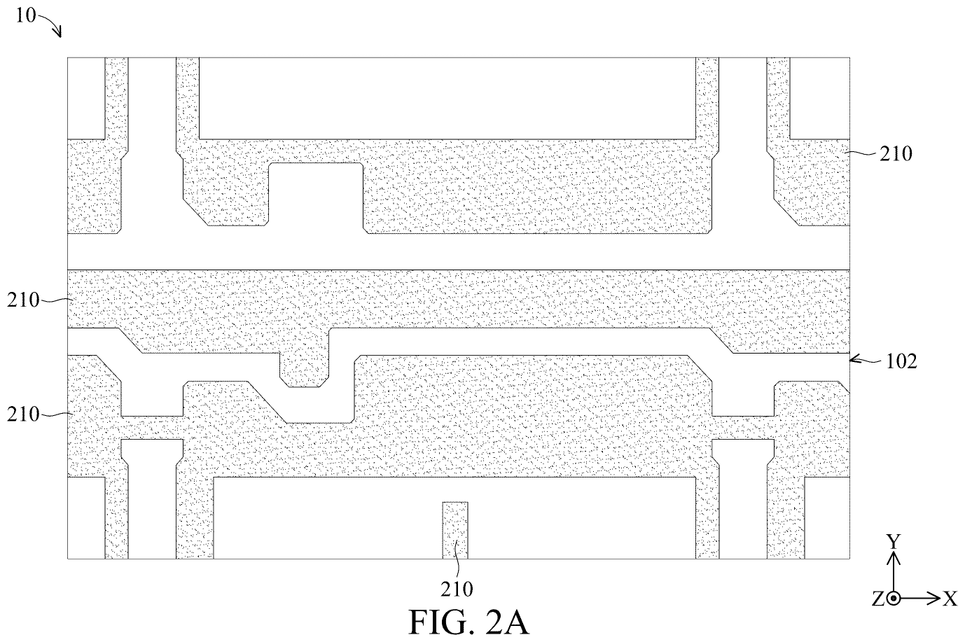

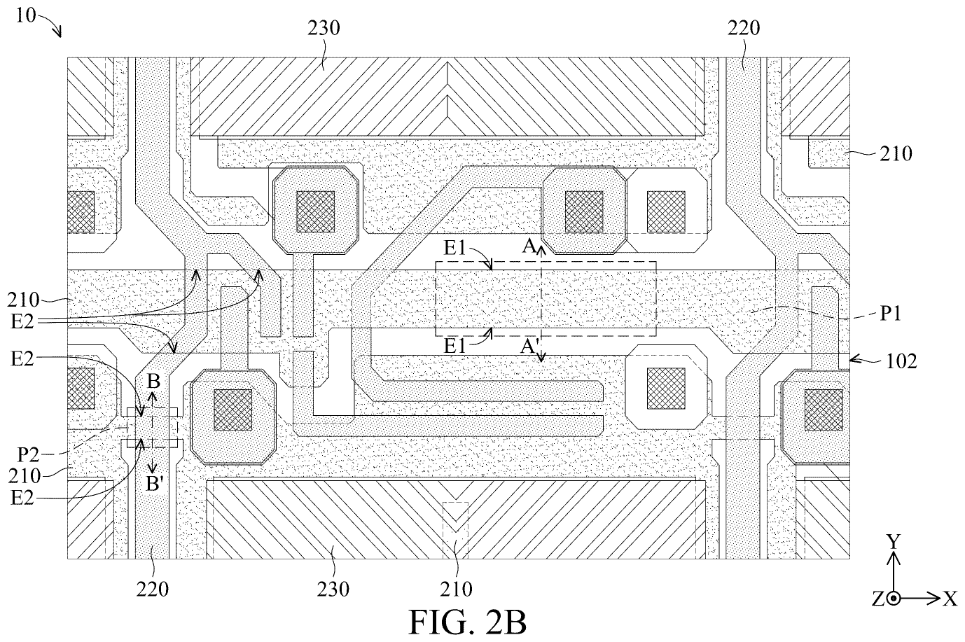

Please refer to FIG. 1, FIG. 2A and FIG. 2B. FIG. 1 is a top-view diagram of an electronic device 10 in accordance with some embodiments of the present disclosure. FIG. 2A and FIG. 2B are partial top-view diagrams of the electronic device 10 in the area A1 of FIG. 1 in accordance with some embodiments of the present disclosure. It should be understood that, for clarity of explanation, some components of the electronic device 10 are omitted in the drawings, and only some components are schematically illustrated. Specifically, FIG. 2A only illustrates the substrate 102 and the first metal layer 210 of the electronic device 10, while FIG. 2B only illustrates the substrate 102, the first metal layer 210, the second metal layer 220 and the electrode layer 230 of the electronic device 10. In accordance with some embodiments, additional features may be added to the electronic device 10 described below.

As shown in FIG. 2A and FIG. 2B, the electronic device 10 includes a substrate 102, a first metal layer 210 and a second metal layer 220. The first metal layer 210 and the second metal layer 220 are disposed on the substrate 102. The second metal layer 220 is disposed on the first metal layer 210. The first metal layer 210 is located between the substrate 102 and the second metal layer 220.

In accordance with some embodiments, the substrate 102 may serve as a driving substrate, and the electronic device 10 may include a driving circuit disposed on the substrate 102. The substrate 102 may include a rigid substrate or a flexible substrate. In accordance with some embodiments, the material of the substrate 102 may include glass, quartz, sapphire, polyimide (PI), polycarbonate (PC), polyethylene terephthalate (PET), polypropylene (PP), polydimethylsiloxane (PDMS), another suitable material or a combination thereof, but it is not limited thereto. In accordance with some embodiments, the substrate 102 may include a flexible printed circuit (FPC). Furthermore, the driving circuit may include an active driving circuit and/or a passive driving circuit. In accordance with some embodiments, the driving circuit may include a thin-film transistor (TFT) (for example, a switching transistor, a driving transistor, a reset transistor, or another thin-film transistor), a data line, a scan line, a common electrode line, a touch signal line, a conductive pad, a dielectric layer, a capacitor or another circuit line, etc., but it is limited thereto. In addition, the thin-film transistor may be a top gate thin-film transistor, a bottom gate thin-film transistor, or a dual gate or double gate thin-film transistor. In accordance with some embodiments, the thin-film transistor includes at least one semiconductor layer, and the semiconductor layer includes, but is not limited to, amorphous silicon, low-temp polysilicon (LTPS), metal oxide, another suitable material, or a combination thereof, but it is not limited thereto. The metal oxide may include indium gallium zinc oxide (IGZO), indium zinc oxide (IZO), indium gallium zinc tin oxide (IGZTO), and another suitable material, or a combination thereof, but it is not limited thereto.

In accordance with some embodiments, the first metal layer 210, for example, serves as a common electrode line, a scan line, a light-shielding element, or the like. In one embodiment, a relatively small side angle corresponds to the scan line. In one embodiment, a relatively large side angle corresponds to the common electrode line and the light-shielding element, but it is not limited thereto. The light-shielding element is, for example, a floating bar, but it is not limited thereto. In accordance with some embodiments, the material of the first metal layer 210 may include copper (Cu), silver (Ag), gold (Au), tin (Sn), aluminum (Al), molybdenum (Mo), tungsten (W), chromium (Cr), nickel (Ni), platinum (Pt), titanium (Ti), palladium (Pd), iridium (Ir), rhodium (Rh), alloys of the aforementioned metals, another suitable metal conductive material or a combination thereof, but it is not limited thereto.

In accordance with some embodiments, the second metal layer 220 serves as a data line, but it is not limited thereto. In the normal direction of the substrate 102 (e.g., the Z direction in the figure), the second metal layer 220 partially overlaps the first metal layer 210. In accordance with some embodiments, data lines and scan lines are interleaved with each other to define multiple pixel units (not labeled). In accordance with some embodiments, the material of the second metal layer 220 may include copper (Cu), silver (Ag), gold (Au), tin (Sn), aluminum (Al), molybdenum (Mo), tungsten (W), chromium (Cr), nickel (Ni), platinum (Pt), titanium (Ti), palladium (Pd), iridium (Ir), rhodium (Rh), alloys of the aforementioned metals, another suitable metal conductive material or a combination thereof, but it is not limited thereto. Furthermore, the material of the second metal layer 220 may be the same as or different from that of the first metal layer 210.

Furthermore, the electronic device 10 may further include an electrode layer 230. The electrode layer 230 is disposed on the substrate 102. The electrode layer 230 is disposed on the first metal layer 210 and the second metal layer 220. In the normal direction of the substrate 102 (e.g., the Z direction in the figure), the electrode layer 230 partially overlaps the first metal layer 210 and the second metal layer 220. In accordance with some embodiments, the electrode layer 230 serves as a pixel electrode, but it is not limited thereto. In accordance with some embodiments, the material of the electrode layer 230 may include transparent conductive oxide (TCO), for example, may include indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), another suitable transparent conductive material or a combination thereof, but it is not limited thereto.

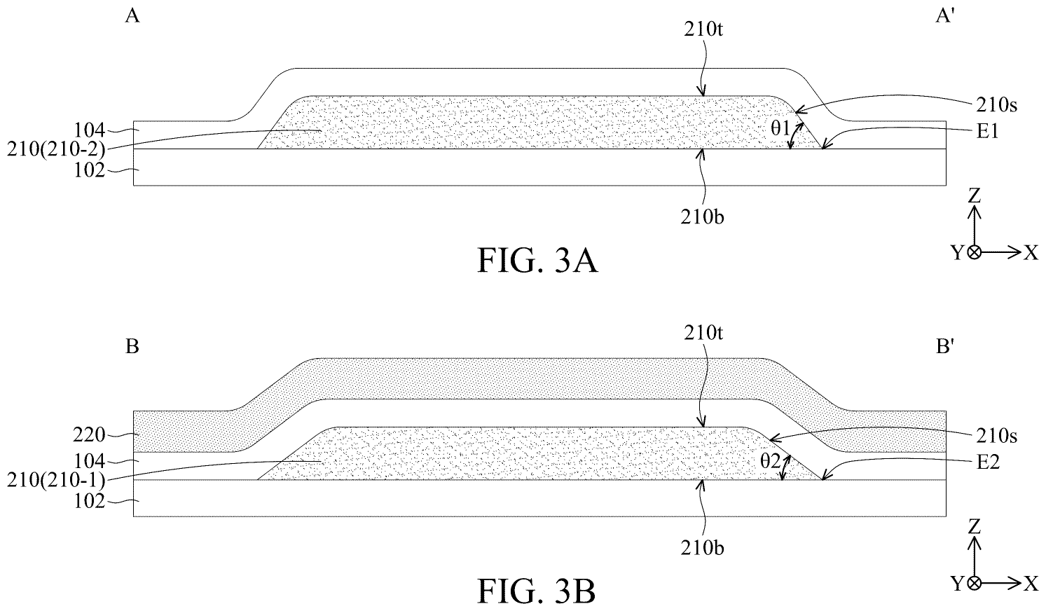

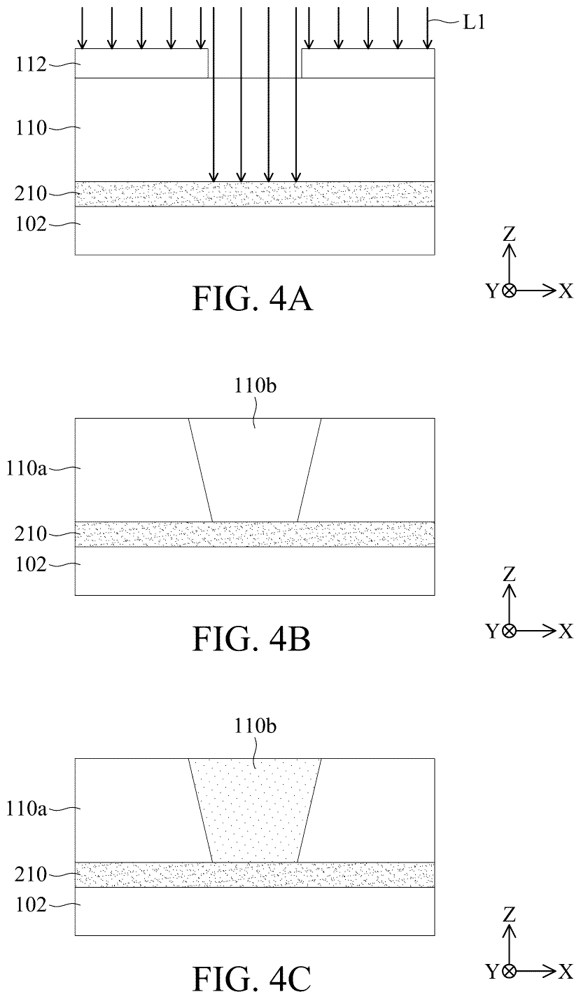

Next, please refer to FIG. 2B, FIG. 3A and FIG. 3B. FIG. 3A is a cross-sectional diagram of the electronic device 10 taken along the section line A-A′ in FIG. 2 in accordance with some embodiments of the present disclosure. FIG. 3B is a cross-sectional diagram of the electronic device 10 taken along the section line B-B′ in FIG. 2 in accordance with some embodiments of the present disclosure.

As shown in FIG. 3A and FIG. 3B, the electronic device 10 may further include an insulating layer 104. The insulating layer 104 is disposed on the first metal layer 210, and is disposed between the first metal layer 210 and the second metal layer 220. In accordance with some embodiments, the material of the insulating layer 104 may include silicon nitride, silicon oxide, silicon oxynitride, phosphosilicate glass (PSG), borosilicate glass (BSG), boron-doped phosphosilicate glass (BPSG), another suitable insulating material, or a combination thereof, but it is not limited thereto.

As shown in FIG. 2B, the first metal layer 210 has a region P1 that substantially does not overlap the second metal layer 220 and a region P2 that substantially overlaps the second metal layer 220. Furthermore, the first metal layer 210 includes a first edge E1 and a second edge E2. The first edge E1 is located in the region P1, and the second edge E2 is located in the region P2. In other words, the first edge E1 does not overlap the second metal layer 220, and the second edge E2 overlaps the second metal layer 220. In addition, in accordance with some embodiments, the region P2 where the first metal layer 210 overlaps the second metal layer 220 is, for example, a scan line, and the region P1 where the first metal layer 210 does not overlap the second metal layer 220 is, for example, a common electrode line. In accordance with some embodiments, the term “edge” can be, for example, the boundary of each layer, or an area that intersects or contacts another interface or another layer, but it is not limited thereto. In accordance with some embodiments, the term “does not overlap” can be, for example, the projections of the first metal layer 210 and the second metal layer 220 do not overlap in the Z direction, or the first metal layer 210 and the second metal layer 220 are separated by a distance in the X direction or Y direction.

Furthermore, as shown in FIG. 3A and FIG. 3B, a side angle θ1 of the first edge E1 is different from a side angle θ2 of the second edge E2, and the side angle θ2 of the second edge E2 is greater than or equal to 30 degrees and less than or equal to 45 degrees (that is, 30degrees≤side angle θ2≤45 degrees), or greater than or equal to 35 degrees and less than or equal to 40 degrees. In accordance with some embodiments, the side angle θ1 of the first edge E1 is greater than the side angle θ2 of the second edge E2 (i.e. the side angle θ1>the side angle θ2). In accordance with some embodiments, the side angle θ1 of the first edge E1 is greater than or equal to 45 degrees and less than or equal to 75 degrees (that is, 45 degrees≤side angle θ1≤75 degrees), or greater than or equal to 50 degrees and less than or equal to 70 degrees, for example, 55 degrees, 60 degrees or 65 degrees, but it is not limited thereto.

Based on the foregoing, in accordance with some embodiments, the side angle θ1 of the first edge E1 that does not overlap the second metal layer 220 is greater than the side angle θ2 of the second edge E2 that overlaps the second metal layer 220. The first metal layer 210, for example, has a larger side angle θ1 (the side profile is relatively steep) at the scan line, and has a smaller side angle θ2 (the side profile is relatively gentle) at the common electrode line. In particular, the foregoing configuration can satisfy the electrical requirements of the first metal layer 210 in different regions. For example, the resistance value of the region of the first metal layer 210 corresponding to the first edge E1 can be smaller than the resistance value of the region corresponding to the second edge E2. In detail, since the common electrode line has a larger side angle θ1, it can have a larger cross-sectional area or volume and thus reduce the resistance value; furthermore, since the scan line has a smaller side angle θ2, it has a flatter side profile, which can reduce the tip discharge caused by the small angle where the first metal layer 210 and the second metal layer 220 overlap or intersect. The problem of electrostatic breakdown or damage to the circuit structure can therefore be reduced.

In addition, in accordance with some embodiments, the first metal layer 210 also has a smaller side angle (not illustrated, the side profile is relatively gentle) in a region serving as a light-shielding element or adjacent to the electrode layer 230, so that the influence of the first metal layer 210 on the arrangement of the display medium (e.g., liquid crystal molecules) can be reduced, thereby improving problems such as brightness unevenness (mura) of the display image. Furthermore, since the first metal layer 210 has less problems with electrostatic discharge when used as a light-shielding element, it can be regarded as having the second edge E2 (not illustrated).

Moreover, the aforementioned side angle refers to the angle between the bottom surface 210b and the side surface 210s of the first metal layer 210 in the cross-sectional diagram.

It should be understood that, in accordance with the embodiments of the present disclosure, an optical microscope (OM), a scanning electron microscope (SEM), a film thickness profiler (α-step), an ellipsometer or another suitable method may be used to measure the distance, spacing or angle between elements, or width or thickness of each element. Specifically, in accordance with some embodiments, a scanning electron microscope may be used to obtain a cross-sectional image including the elements to be measured, and the distance, spacing or angle between elements, or width or thickness of each element in the image can be measured.

In addition, in accordance with some embodiments, the side surface 210s of the first metal layer 210 has an arc-shaped profile (for example, the first metal layer 210 may have an arc-shaped top corner). In other words, the side surface 210s and the top surface 210t of the first metal layer 210 may not have a sharp angle shape, or the junction of the side surface 210s and the top surface 210t of the first metal layer 210 may have a curvature. It is noted that this configuration can also reduce the risk of tip discharge in the first metal layer 210, thereby reducing the problem of electrostatic breakdown or damage to the circuit structure.

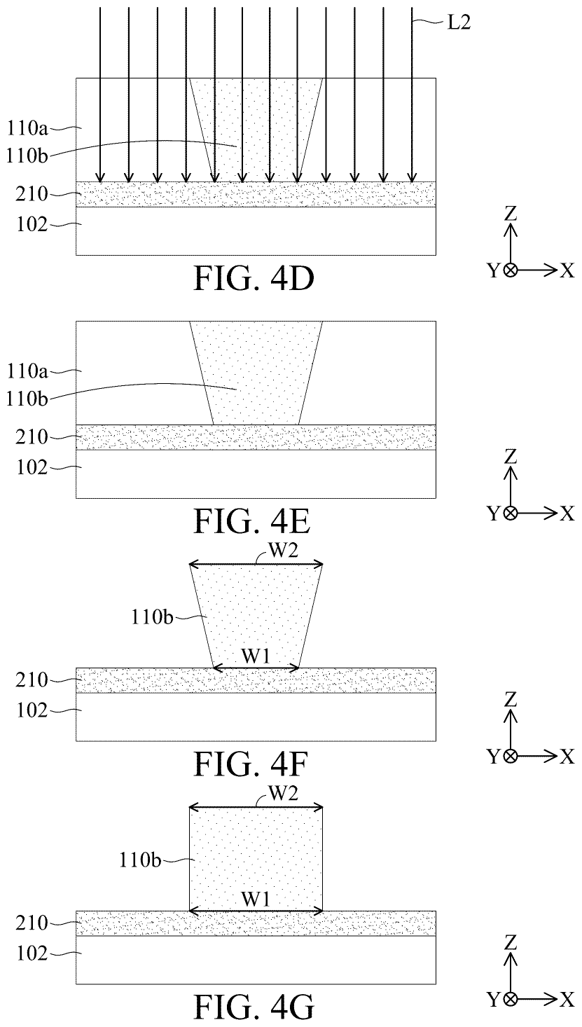

Next, please refer to FIGS. 4A to 4G, which are cross-sectional diagrams of an electronic device during the intermediate stages of the manufacturing process in accordance with some embodiments of the present disclosure. It should be understood that, for clarity of explanation, some components of the electronic device are omitted in the drawings, and only some components are schematically illustrated. In accordance with some embodiments, additional operating steps may be provided before, during, and/or after the manufacturing method of the electronic device. In accordance with some embodiments, some of the operation steps described may be replaced or omitted, and the order of some of the operation steps described may be interchangeable.

Specifically, FIGS. 4A to 4G show the patterning process of the first metal layer 210, and particularly the photolithography process in the patterning process. In accordance with some embodiments, the photolithography process may include photoresist coating (e.g., spin coating), soft baking, hard baking, mask alignment, exposure, post-exposure baking, photoresist development, cleaning and drying, etc., which will be explained in detail below.

First, referring to FIG. 4A, a substrate 102 is provided, and a first metal layer 210 is formed on the substrate 102. Next, a patterning process is performed on the first metal layer 210. In detail, the photoresist layer 110 is formed on the first metal layer 210, and a mask 112 is formed on the photoresist layer 110 to define the pattern of the photoresist layer 110. For example, the mask 112 may be used to cover the portion of the photoresist layer 110 to be removed. In accordance with some embodiments, the patterning process uses an image reversal resist as the photoresist layer 110. Next, a first exposure step L1 is performed on the photoresist layer 110.

In accordance with some embodiments, the first metal layer 210 may be formed by a physical vapor deposition (PVD) process, an electroplating process, an electroless plating process, another suitable method, or a combination thereof.

Referring to FIG. 4B, the mask 112 is removed, and the first exposure step L1 can convert the portion 110b of the photoresist layer 110 that is not blocked by the mask 112 (i.e. the exposed portion) into soluble, and convert the portion 110a of the photoresist layer 110 that is blocked by the mask 112 (i.e. the unexposed portion) into insoluble.

Next, referring to FIG. 4C, a reversal bake is performed on the photoresist layer 110, so that the portion 110b of the photoresist layer 110 undergoes a cross-linking reaction and being inert (the dots in the figure represent the portion 110b that has been cross-linked), while the unexposed portion 110a is still photoactive.

Next, referring to FIG. 4D, a second exposure step L2 is performed on the portion 110a and the portion 110b of the photoresist layer 110. The second exposure step L2 may be a flood exposure. That is, no mask is used in the second exposure step L2.

Referring to FIG. 4E, the second exposure step L2 can convert the portion 110a of the photoresist layer 110 (the portion not exposed in the first exposure step L1) into soluble, while the portion 110b of the photoresist layer 110 (the portion exposed in the first exposure step L1) is still insoluble. Then, the steps such as development, cleaning, and drying can be performed to remove the portion 110a of the photoresist layer 110.

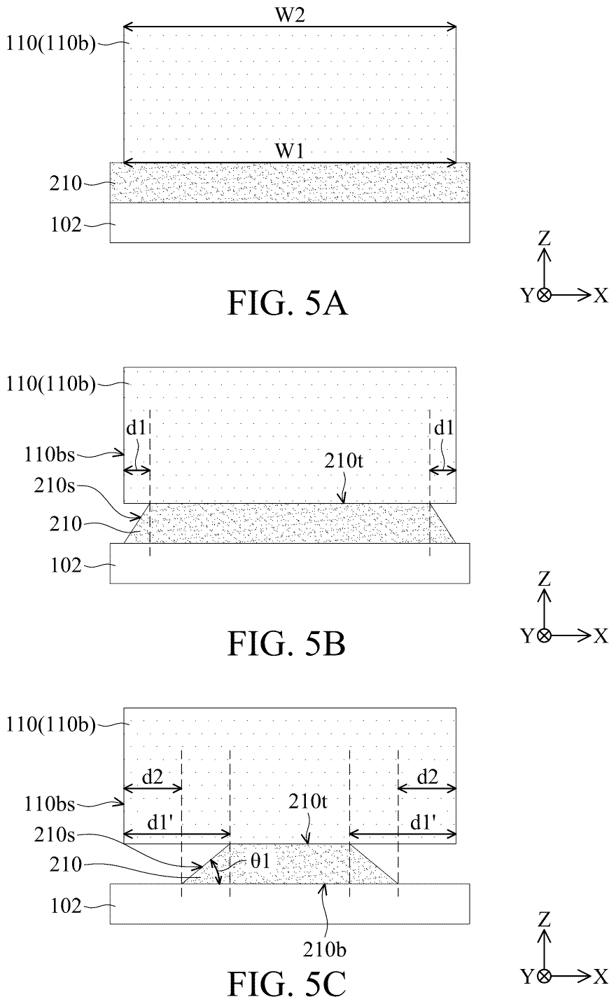

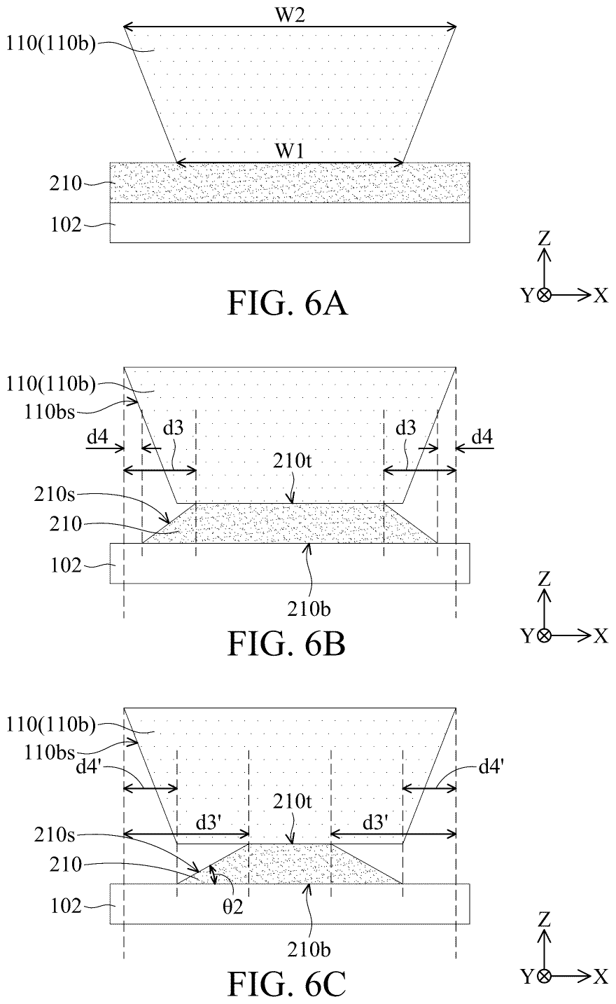

As shown in FIG. 4F and FIG. 4G, after the steps of development, cleaning and drying, the portion 110b of the photoresist layer 110 (the portion exposed in the first exposure step L1) remains on the first metal layer 210. The remaining portion 110b of the photoresist layer 110 can be used to perform an etching step on the first metal layer 210 (which will be described in FIGS. 5A to 5C and FIGS. 6A to 6C).

It is noted that FIG. 4F and FIG. 4G show the aspects of the remaining portion 110b of the photoresist layer 110 in different embodiments. In accordance with some embodiments, the developed photoresist can have different aspects by controlling the intensity of exposure. In detail, the profile of the remaining portion 110b of the photoresist layer 110 can be controlled by adjusting the exposure dose of the first exposure step L1 (e.g., adjusting the intensity or time). As shown in FIG. 4F, a lower exposure dose results in lower adhesion between the photoresist and the first metal layer 210, so the portion 110b of the photoresist layer 110 with a bottom surface width W1 smaller than a top surface width W2 can be obtained. As shown in FIG. 4G, a higher exposure dose can obtain the portion 110b of the photoresist layer 110 whose bottom surface width W1 is substantially the same as the top surface width W2. In accordance with some embodiments, the patterning process may use the same mask to simultaneously form portions 110b of the photoresist layer 110 with different profiles. In accordance with some embodiments, a halftone mask or a gray tone mask may be used to allow the photoresist layer 110 to have different exposure doses in different regions.

Next, refer to FIGS. 5A to 5C, which are cross-sectional diagrams of an electronic device during the intermediate stages of the manufacturing process in accordance with some embodiments of the present disclosure. It should be understood that, for clarity of explanation, some components of the electronic device are omitted in the drawings, and only some components are schematically illustrated.

Specifically, FIGS. 5A to 5C show the patterning process of the first metal layer 210 that is performed following FIG. 4G, and particularly the etching process in the patterning process. In accordance with some embodiments, a wet etching step is used in the patterning process. As shown in FIG. 5A, the portion 110b of the photoresist layer 110 whose bottom surface width W1 is substantially the same as the top surface width W2 is disposed on the first metal layer 210, and then a wet etching step is performed on the first metal layer 210. As shown in FIG. 5B, due to the isotropic etching characteristics and flow field effect of the wet etching step, the side surface 210s of the first metal layer 210 can be recessed inward. For example, there can be a first distance d1 between the top surface 210t of the first metal layer 210 and the side surface 110bs of the portion 110b of the photoresist layer 110. As shown in FIG. 5C, as the wet etching step proceeds, the side surface 210s of the first metal layer 210 continues to be recessed inward, such that the first distance dl is increased to the first distance d1′, and there also can be a second distance d2 between the bottom surface 210b of the first metal layer 210 and the side surface 110bs of the portion 110b of the photoresist layer 110. In accordance with some embodiments, the first distance dl' is greater than the first distance d1, and the first distance d1′ is greater than the second distance d2. Furthermore, there is a relatively large side angle θ1 between the side surface 210s and the bottom surface 210b of the first metal layer 210.

Furthermore, the aforementioned first distance d1 and first distance d1′ refer to the maximum distance between the top surface 210t of the first metal layer 210 and the side surface 110bs of portion 110b of photoresist layer 110 in the direction perpendicular to the normal direction of the substrate 102 (e.g., the X direction in the figure). The aforementioned second distance d2 refers to the maximum distance between the bottom surface 210b of the first metal layer 210 and the side surface 110bs of the portion 110b of the photoresist layer 110 in the direction perpendicular to the normal direction of the substrate 102 (e.g., the X direction in the figure).

Next, referring to FIGS. 6A to 6C, which are cross-sectional diagrams of an electronic device during the intermediate stages of the manufacturing process in accordance with some embodiments of the present disclosure. It should be understood that, for clarity of explanation, some components of the electronic device are omitted from the drawings, and only some components are schematically illustrated.

Specifically, FIGS. 6A to 6C show the patterning process of the first metal layer 210 that is performed following FIG. 4G, and particularly the etching process in the patterning process. In accordance with some embodiments, the patterning process uses a wet etching step. As shown in FIG. 6A, the portion 110b of the photoresist layer 110 whose bottom surface width W1 is smaller than the top surface width W2 is disposed on the first metal layer 210, and then a wet etching step is performed on the first metal layer 210. As shown in FIG. 6B, due to the isotropic etching characteristics and flow field effect of the wet etching step, the side surface 210s of the first metal layer 210 can be recessed inward. For example, there can be a third distance d3 between the top surface 210t of the first metal layer 210 and the side surfaces 110bs of the portion 110b of the photoresist layer 110, and there can be a fourth distance d4 between the bottom surface 210b of the first metal layer 210 and the side surfaces 110bs of the portion 110b of the photoresist layer 110. As shown in FIG. 6C, as the wet etching step proceeds, the side surface 210s of the first metal layer 210 continues to be recessed inward, such that the third distance d3 is increased to the third distance d3′, and the fourth distance d4 is increased to the fourth distance d4′. In accordance with some embodiments, the third distance d3′ is greater than the third distance d3, the fourth distance d4′ is greater than the fourth distance d4, and the third distance d3′ is greater than the fourth distance d4′. Furthermore, there is a relatively small side angle θ2 between the side surface 210s and the bottom surface 210b of the first metal layer 210.

Moreover, the aforementioned third distance d3 and third distance d3′ refer to the maximum distance between the top surface 210t of the first metal layer 210 and the side surface 110bs of portion 110b of photoresist layer 110 in the direction perpendicular to the normal direction of the substrate 102 (e.g., the X direction in the figure). The aforementioned fourth distance d4 and fourth distance d4′ refer to the maximum distance between the bottom surface 210b of the first metal layer 210 and the side surfaces 110bs of portion 110b of the photoresist layer 110 in the direction perpendicular to the normal direction of the substrate 102 (e.g., the X direction in the figure).

Based on the foregoing, in accordance with the embodiments of the present disclosure, the first metal layer 210 can have different profiles in different regions without increasing the number of masks or the number of deposition and etching steps. Specifically, refer to FIG. 2B. The exposure dose of the aforementioned patterning process in the region

P1 corresponding to the first edge E1 of the first metal layer 210 is different from that of the region P2 corresponding to the second edge E2 of the first metal layer 210. The exposure dose causes the first metal layer 210 to have different profiles at the first edge E1 and the second edge E2. More specifically, the exposure dose of the region P1 corresponding to the first edge E1 (as shown in FIG. 4G and FIGS. 5A to 5C) may be greater than the exposure dose of the region P2 corresponding to the second edge E2 (as shown in FIG. 4F and FIGS. 6A to 6C), thereby making the side angle θ1 of the first edge E1 larger than the side angle θ2 of the second edge E2. However, according to the characteristics of the photoresist material, the exposure dose of the region P1 corresponding to the first edge E1 may be smaller than the exposure dose of the region P2 corresponding to the second edge E2 in accordance with some embodiments. As mentioned above, in accordance with some embodiments, the side angle θ1 of the first edge E1 is greater than or equal to 45 degrees and less than or equal to 75 degrees (i.e. 45 degrees≤side angle θ1≤75 degrees), or greater than or equal to 50 degrees and less than or equal to 70 degrees, for example, 55 degrees, 60 degrees or 65 degrees, but it is not limited thereto. In accordance with some embodiments, the side angle θ2 of the second edge E2 is greater than or equal to 30 degrees and less than or equal to 45 degrees (i.e. 30 degrees≤side angle θ2≤45 degrees), or greater than or equal to 35 degrees and less than or equal to 40 degrees.

In accordance with some embodiments, different etching liquids may be selected in the wet etching steps corresponding to different regions to assist in forming different side angles. For example, an etching solution with an etching inhibitor added may be used at the first edge E1 that does not overlap the second metal layer 220, while no etching inhibitor is added at the second edge E2 that overlaps the second metal layer 220.

In addition, in accordance with some embodiments, the second metal layer 220 is formed on the first metal layer 210 after the patterning process of the first metal layer 210. In accordance with some embodiments, the insulating layer 104 is formed on the first metal layer 210 before the second metal layer 220 is formed, so that the insulating layer 104 is disposed between the first metal layer 210 and the second metal layer 220. In accordance with some embodiments, the material of the insulating layer 104 may include, for example, silicon nitride (SiNx), silicon oxide (SiOx), silicon oxynitride (SiOxNy), epoxy resin, acrylic, bismaleimide, polyimide or a combination thereof, but it is not limited thereto.

In accordance with some embodiments, the insulating layer 104 may be formed on the first metal layer 210 through a chemical vapor deposition process, a physical vapor deposition process, a coating process, a printing process, another suitable process, or a combination thereof. Furthermore, the second metal layer 220 may be formed on the insulating layer 104 through a physical vapor deposition (PVD) process, an electroplating process, an electroless plating process, another suitable method, or a combination thereof.

To summarize the above, in accordance with the embodiments of the present disclosure, an electronic device is provided that includes metal layers with different profiles in particular regions. Specifically, different regions of the same metal layer (for example, scan line, common electrode line, light-shielding element, etc.) can have different side angles, thereby allowing the same metal layer to have appropriate electrical requirements in different regions according to different functions. In this way, the problem of electrostatic discharge (ESD) occurring between metal layers and damaging the circuit structure can be reduced, which may further improve the quality of the displayed image. Furthermore, in accordance with the embodiments of the present disclosure, the method of manufacturing the electronic device provided allows the same metal layer to have different profiles in different regions without increasing the number of masks or the number of deposition and etching steps.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
a substrate;
a first metal layer disposed on the substrate, the first metal layer comprising a
first edge and a second edge; and
a second metal layer disposed on the first metal layer, wherein the first metal layer is located between the substrate and the second metal layer;
wherein the first edge does not overlap the second metal layer, the second edge overlaps the second metal layer, a side angle of the first edge is different from a side angle of the second edge, and the side angle of the second edge is greater than or equal to 30 degrees and less than or equal to 45 degrees.

The electronic device as claimed in claim 1, wherein the side angle of the first edge is greater than the side angle of the second edge.

3. The electronic device as claimed in claim 1, wherein the side angle of the first edge is greater than or equal to 45 degrees and less than or equal to 75 degrees.

4. The electronic device as claimed in claim 1, wherein a side surface of the first metal layer has an arc-shaped profile.

5. The electronic device as claimed in claim 1, wherein the first edge is located in a region of the first metal layer serving as a scan line.

6. The electronic device as claimed in claim 1, wherein the second edge is located in a region of the first metal layer serving as a common electrode line.

7. The electronic device as claimed in claim 1, wherein the second edge is located in a region of the first metal layer serving as a light-shielding element.

8. The electronic device as claimed in claim 1, further comprising an insulating layer disposed between the first metal layer and the second metal layer. 9. The electronic device as claimed in claim 1, wherein a resistance value of a

region of the first metal layer corresponding to the first edge is smaller than a resistance value of a region corresponding to the second edge. 10. The electronic device as claimed in claim 1, wherein the second metal layer

serves as a data line.

11. A method of manufacturing an electronic device, comprising:
providing a substrate;
forming a first metal layer on the substrate, the first metal layer comprising a first edge and a second edge;
performing a patterning process on the first metal layer; and
forming a second metal layer on the first metal layer;
wherein an exposure dose of the patterning process in a region corresponding to the first edge is different from an exposure dose in a region corresponding to the second edge, so that the first metal layer has different profiles at the first edge and the second edge, wherein the first edge does not overlap the second metal layer, the second edge overlaps the second metal layer, a side angle of the first edge is different from a side angle of the second edge, and the side angle of the second edge is greater than or equal to 30 degrees and less than or equal to 45 degrees.

12. The method of manufacturing an electronic device as claimed in claim 11, wherein the patterning process uses the same mask.

13. The method of manufacturing an electronic device as claimed in claim 11, wherein the exposure dose in the region corresponding to the first edge is greater than the exposure dose in the region corresponding to the second edge.

14. The method of manufacturing an electronic device as claimed in claim 11, wherein the patterning process uses an image reversal resist.

15. The method of manufacturing an electronic device as claimed in claim 11, wherein the patterning process uses a wet etching step.

16. The method of manufacturing an electronic device as claimed in claim 11, wherein the side angle of the first edge is greater than the side angle of the second edge.

17. The method of manufacturing an electronic device as claimed in claim 11, wherein the side angle of the first edge is greater than or equal to 45 degrees and less than or equal to 75 degrees.

18. The method of manufacturing an electronic device as claimed in claim 11, wherein the first edge is located in a region of the first metal layer serving as a scan line.

19. The method of manufacturing an electronic device as claimed in claim 11, wherein the second edge is located in a region of the first metal layer serving as a common electrode line.

20. The method of manufacturing an electronic device as claimed in claim 11, further comprising forming an insulating layer on the first metal layer, wherein the insulating layer is disposed between the first metal layer and the second metal layer.
